(19) United States
(12) Patent Application Publication
(10) Pub. No.: US 2022/0102196 A1
(43) Pub. Date: Mar. 31, 2022

(54) METHOD OF MANUFACTURING SEMICONDUCTOR STRUCTURE

(71) Applicant: NANYA TECHNOLOGY CORPORATION, New Taipei City (TW)

(72) Inventors: Ying-Cheng CHUANG, Taoyuan City (TW); Che-Hsien LIAO, New Taipei City (TW)

(21) Appl. No.: 17/643,402

(22) Filed: Dec. 8, 2021

Related U.S. Application Data
(62) Division of application No. 16/941,526, filed on Jul. 28, 2020.

(51) Int. Cl. H01L 21/762

(52) U.S. Cl. CPC H01L 21/76237; H01L 21/02271; H01L 21/76227

(57) ABSTRACT

A method of manufacturing a semiconductor structure includes: etching a substrate according to a hard mask to form a plurality of trenches in the substrate; performing a nitridation treatment on the trenches of the substrate; filling the trenches of the substrate with a flowable isolation material; and solidifying the flowable isolation material to form an isolation material. A semiconductor structure manufactured by the method is also provided.

### CROSS-REFERENCE TO RELATED APPLICATION

The present application is a Divisional Application of U.S. application Ser. No. 16/941,526, filed Jul. 28, 2020, which is herein incorporated by reference in their entirety.

### BACKGROUND

### Field of Invention

The present invention relates to a method of manufacturing a semiconductor structure.

### Description of Related Art

In a semiconductor device, an isolation structure is formed between active areas (AA) for electrically insulated the active areas. As semiconductor devices become smaller and highly integrated, the pitch of the active areas continue to shrink. Accordingly, the size of the isolation structure continues to shrink as well.

However, shrinkage of the pitch of the active areas and shrinkage of the size of the isolation structure may cause some problems, such as toppling of the active areas during processes of forming the isolation structure.

### SUMMARY

The present invention provides a method of manufacturing a semiconductor structure which can solve the issue of toppling of active regions.

In accordance with an aspect of the present invention, a method of manufacturing a semiconductor structure includes: etching a substrate according to a hard mask to form a plurality of trenches in the substrate; performing a nitridation treatment on the trenches of the substrate; filling the trenches of the substrate with a flowable isolation material; and solidifying the flowable isolation material to form an isolation material.

According to some embodiments of the present invention, the nitridation treatment includes decoupled plasma nitridation (DPN), rapid thermal nitridation (RTN) or a combination thereof.

According to some embodiments of the present invention, there are nitrogen atoms on a side surface of each of the trenches after performing the nitridation treatment on the trenches of the substrate.

According to some embodiments of the present invention, the method further includes performing an oxidation treatment on the trenches of the substrate before performing the nitridation treatment on the trenches of the substrate.

According to some embodiments of the present invention, performing the oxidation treatment on the trenches of the substrate includes forming an oxide-containing layer on a side surface of each of the trenches, and there are nitrogen atoms on a side surface of the oxide-containing layer after performing the nitridation treatment on the trenches of the substrate.

According to some embodiments of the present invention, filling the trenches of the substrate with the flowable isolation material is conducted by using a flowable chemical vapor deposition (CVD) process.

According to some embodiments of the present invention, solidifying the flowable isolation material includes using a UV curing process, an annealing process or a combination thereof.

According to some embodiments of the present invention, the method further includes forming a hard mask layer over the substrate before etching the substrate; and removing a plurality of portions of the hard mask layer to form the hard mask.

According to some embodiments of the present invention, a width of the trench is in a range of from 8 nm to 30 nm.

According to some embodiments of the present invention, a ratio of a depth of the trench to a width of the trench is in a range of from 8 to 18.

The present invention also provides a semiconductor structure manufactured by the method mentioned above.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIGS. 1 to 7 are cross-sectional views of a method of manufacturing a semiconductor structure at various stages in accordance with some embodiments of the present invention.

FIGS. 8 to 11 are cross-sectional views of a method of manufacturing a semiconductor structure following FIG. 4 in accordance with some embodiments of the present invention.

FIG. 12 is a SEM image of a semiconductor structure formed without a nitridation treatment.

FIG. 13 is a SEM image of a semiconductor structure formed with a nitridation treatment in accordance with some embodiments of the present invention.

### DETAILED DESCRIPTION

In order that the present disclosure is described in detail and completeness, implementation aspects and specific embodiments of the present disclosure with illustrative description are presented, but it is not the only form for implementation or use of the specific embodiments of the present disclosure. The embodiments disclosed herein may be combined or substituted with each other in an advantageous manner, and other embodiments may be added to an embodiment without further description. In the following description, numerous specific details will be described in detail in order to enable the reader to fully understand the following embodiments. However, the embodiments of the present disclosure may be practiced without these specific details.

Further, spatially relative terms, such as “beneath,” “over,” and the like, may be used herein for ease of description to describe one element or feature's relationship to another element(s) or feature(s) as shown in the figures. The true meaning of the spatially relative terms includes other orientations. For example, when the figure is flipped up and down by 180 degrees, the relationship between one component and another component may change from “beneath” to “over.” In addition, the spatially relative descriptions used herein should be interpreted the same.

As mentioned in the related art, toppling of the active areas may occur during processes of forming the isolation structure. Specifically, when a flowable isolation material flows to fill a plurality of trenches between the active areas, a lateral force is generated to the active areas, which may topple the active areas, resulting in contact with adjacent active areas. Therefore, toppling of the active areas will induce twin bit fail issue. Also, a wafer acceptance test (WAT) shows bit line (BL)-bit line (BL) leakage issue. Therefore, the present disclosure provides a method of manufacturing a semiconductor structure including performing a nitridation treatment, which can significantly prevent toppling of the active areas. Embodiments of the method of manufacturing the semiconductor structure will be described in detail below.

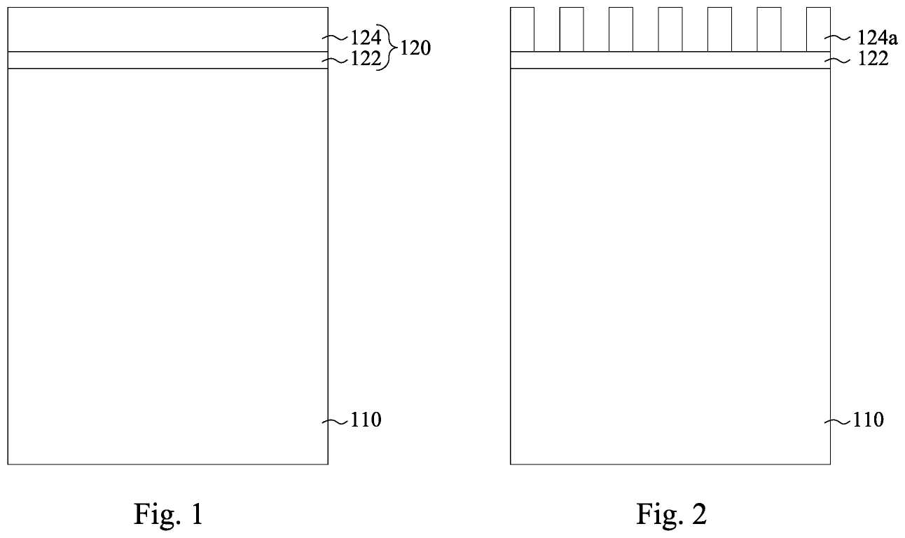

FIGS. 1 to 7 are cross-sectional views of a method of manufacturing a semiconductor structure at various stages in accordance with some embodiments of the present invention.

As shown in FIG. 1, a substrate 110 is provided. In some embodiments, the substrate 110 includes an elementary semiconductor including silicon or germanium in crystal, polycrystalline, and/or an amorphous structure; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; any other suitable material; and/or a combination thereof.

In some embodiments, a hard mask layer 120 is formed over the substrate 110 before etching the substrate 110. Formation of the hard mask layer 120 may include any suitable deposition method, such as plasma-enhanced atomic layer deposition (PEALD), chemical vapor deposition (CVD), plasma-enhanced chemical vapor deposition (PECVD), physical vapor deposition (PVD), and the like. In some embodiments, the hard mask layer 120 may include silicon nitride, silicon oxide, silicon oxynitride, silicon carbide, or the like.

In some embodiments, the hard mask layer 120 may include one or more layers. In some embodiments, as shown in FIG. 1, the hard mask layer 120 includes a first hard mask layer 122 and a second hard mask layer 124 over the first hard mask layer 122, which may be made of different materials. In some embodiments, the first hard mask layer 122 is made of silicon oxide and may be called as a pad oxide layer, and the second hard mask layer 124 is made of silicon nitride and may be called as a pad nitride layer. In some embodiments, the second hard mask layer 124 has a thickness greater than a thickness of the first hard mask layer 122, but not limited thereto.

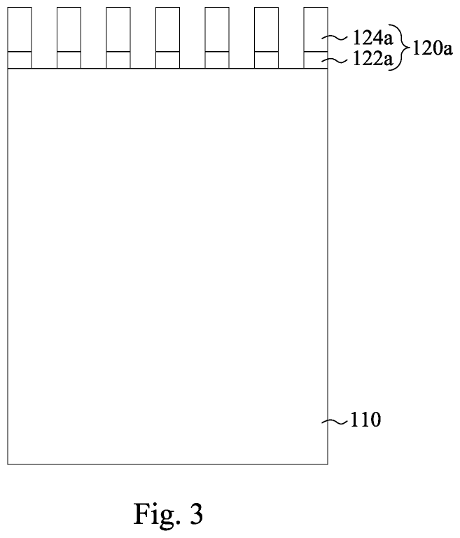

As shown in FIGS. 1 to 3, a plurality of portions of the hard mask layer 120 are removed to form a hard mask 120a. In some embodiments, as shown in FIGS. 1 and 2, a plurality of portions of the second hard mask layer 124 are removed to form a second hard mask 124a exposing a plurality portions of the first mask layer 122; as shown in FIGS. 2 and 3, the exposed portions of the first mask layer 122 are removed to form a first hard mask 122a. As shown in FIG. 3, after the hard mask 120a is formed, a plurality of portions of the substrate 110 are exposed.

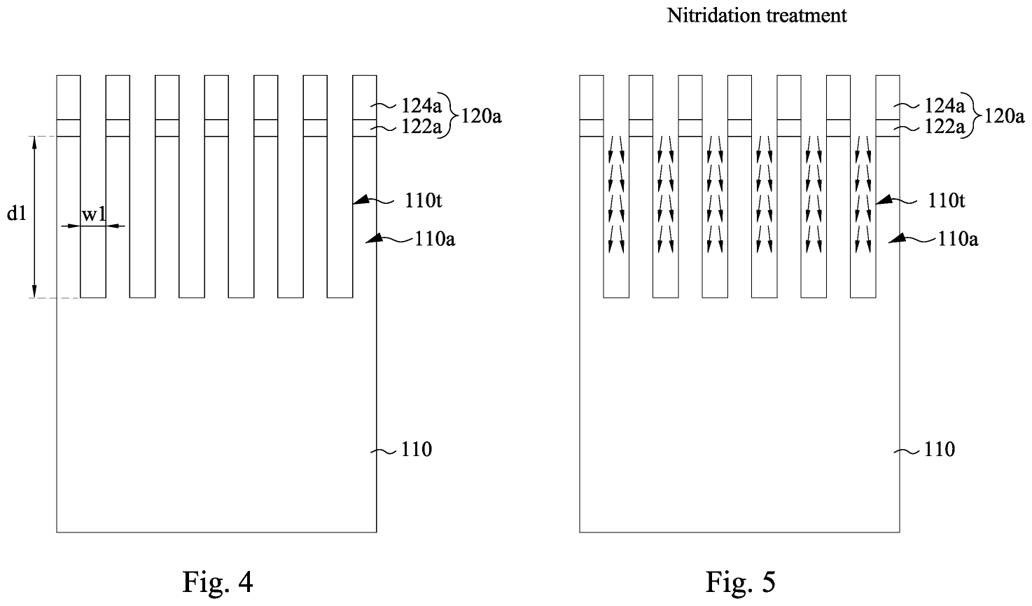

Next, as shown in FIGS. 3 and 4, the substrate 110 is etched according to the hard mask 120a to form a plurality of trenches 110t in the substrate 110. In other words, the substrate 110 is etched to define a plurality of island-shaped active regions 110a. In some embodiments, the substrate 110 is etched by performing a dry etching process, such as a reactive ion etching (RIE) process, but not limited thereto.

In some embodiments, as shown in FIGS. 2 to 4, the first mask layer 122 and the substrate 110 therebeneath are etched according to the second hard mask 124a to form the first mask 122a and the trenches 110t in the substrate 110. In some embodiments, the first mask layer 122 and the substrate 110 therebeneath are etched by performing a dry etching process, such as a RIE process, but not limited thereto.

In some embodiments, as shown in FIG. 4, a width w1 of the trench 110t is in a range of from 8 nm to 30 nm. In some embodiments, the width w1 of the trench 110t is in a range of from 8 nm to 25 nm. In some embodiments, a ratio of a depth dl of the trench 110t to the width w1 of the trench 110t is in a range of from 8 to 18.

Subsequently, as shown in FIGS. 4 and 5, a nitridation treatment is performed on the trenches 110t of the substrate 110. In some embodiments, the nitridation treatment includes decoupled plasma nitridation (DPN), rapid thermal nitridation (RTN) or a combination thereof. In some embodiments, after the nitridation treatment is performed, the side surface of each of the trenches 110t is hydrophobic, and a water contact angle of the side surface of each of the trenches 110t is greater than 90 degrees.

In some embodiments, there are nitrogen atoms on the side surface of each of the trenches 110t after performing the nitridation treatment on the trenches 110t of the substrate 110. In some embodiments, the nitrogen atoms from the nitridation treatment is doped into the side surface of each of the trenches 110t. In some embodiments, the substrate 110 includes silicon, and the side surface of each of the trenches 110t includes nitrogen-doped silicon, silicon nitride or a combination thereof.

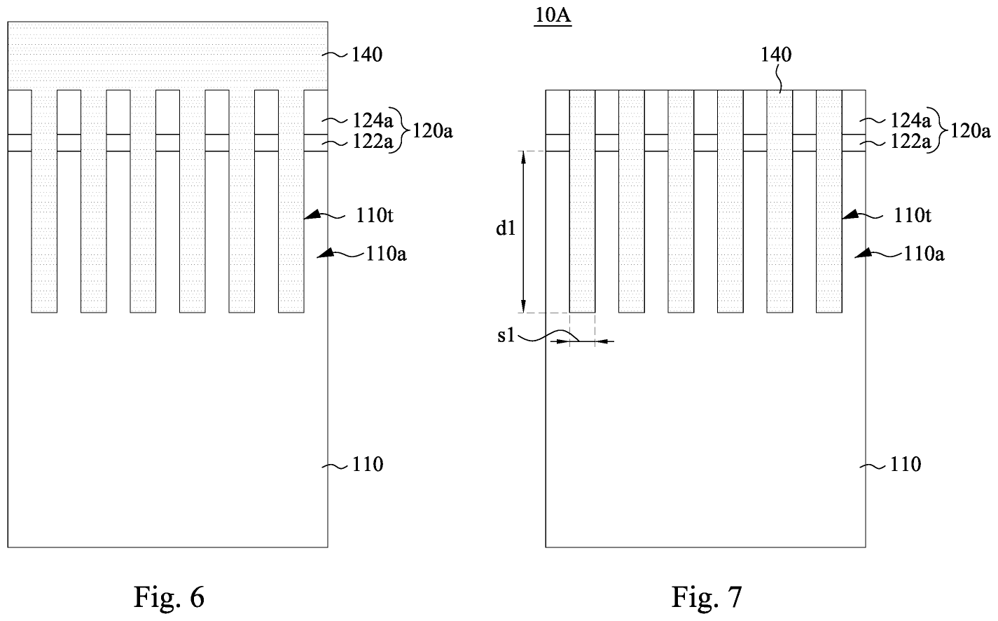

Subsequently, as shown in FIGS. 5 and 6, the trenches 110t of the substrate 110 are filled with a flowable isolation material, and the flowable isolation material is then solidified to form an isolation material 140. In some embodiments, filling the trenches 110t of the substrate 110 with the flowable isolation material is conducted by using a flowable chemical vapor deposition (CVD) process. In some embodiments, solidifying the flowable isolation material includes using a UV curing process, an annealing process or a combination thereof.

In some embodiments, the flowable isolation material includes polysilazane based spin-on dielectric, or the like, but not limited thereto. In some embodiments, the flowable isolation material may have a repeated unit of —HN—SiH₂—NH—.

In some embodiments, when the flowable isolation material flows to fill the trenches 110t, a lateral force is generated to the active regions 110a. However, the inventor found that since the nitridation treatment is previously performed, toppling of the active regions 110a will not occur.

Next, as shown in FIGS. 6 and 7, a planarization process is performed to remove the isolation material 140 over the hard mask 120a. In some embodiments, the planarization process includes chemical mechanical planarization (CMP). In some embodiments, the second hard mask 124a is acted as a stop layer during the planarization process. In some embodiments, after the planarization process is performed, an upper surface of the second hard mask 124a is exposed.

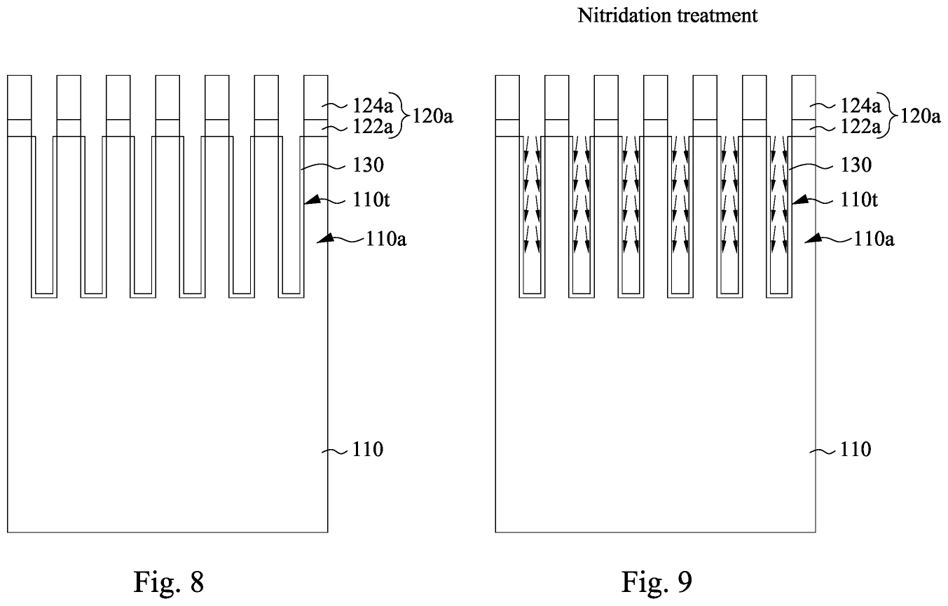

FIGS. 8 to 11 are cross-sectional views of a method of manufacturing a semiconductor structure following FIG. 4 in accordance with some embodiments of the present invention.

As shown in FIGS. 4 and 8, an oxidation treatment is performed on the trenches 110t of the substrate 110 before performing the nitridation treatment on the trenches 110t of the substrate 110. In some embodiments, performing the oxidation treatment on the trenches 110t of the substrate 110 includes forming an oxide-containing layer 130 on a side surface of each of the trenches 110t.

Subsequently, as shown in FIGS. 8 and 9, a nitridation treatment is performed on the trenches 110t of the substrate 110. In some embodiments, the nitridation treatment includes DPN, RTN or a combination thereof. In some embodiments, after the nitridation treatment is performed, a side surface of the oxide-containing layer 130 is hydrophobic, and a water contact angle of the side surface of the oxide-containing layer 130 is greater than 90 degrees.

In some embodiments, there are nitrogen atoms on the side surface of the oxide-containing layer 130 after performing the nitridation treatment on the trenches 110t of the substrate 110. In some embodiments, the nitrogen atoms from the nitridation treatment is doped into the side surface of the oxide-containing layer 130. In some embodiments, the side surface of the oxide-containing layer 130 includes nitrogen-doped oxide, oxynitride or a combination thereof.

Subsequently, as shown in FIGS. 9 and 10, the trenches 110t of the substrate 110 are filled with a flowable isolation material, and the flowable isolation material is then solidified to form an isolation material 140. In some embodiments, filling the trenches 110t of the substrate 110 with the flowable isolation material is conducted by using a flowable CVD process. In some embodiments, solidifying the flowable isolation material includes using a UV curing process, an annealing process or a combination thereof.

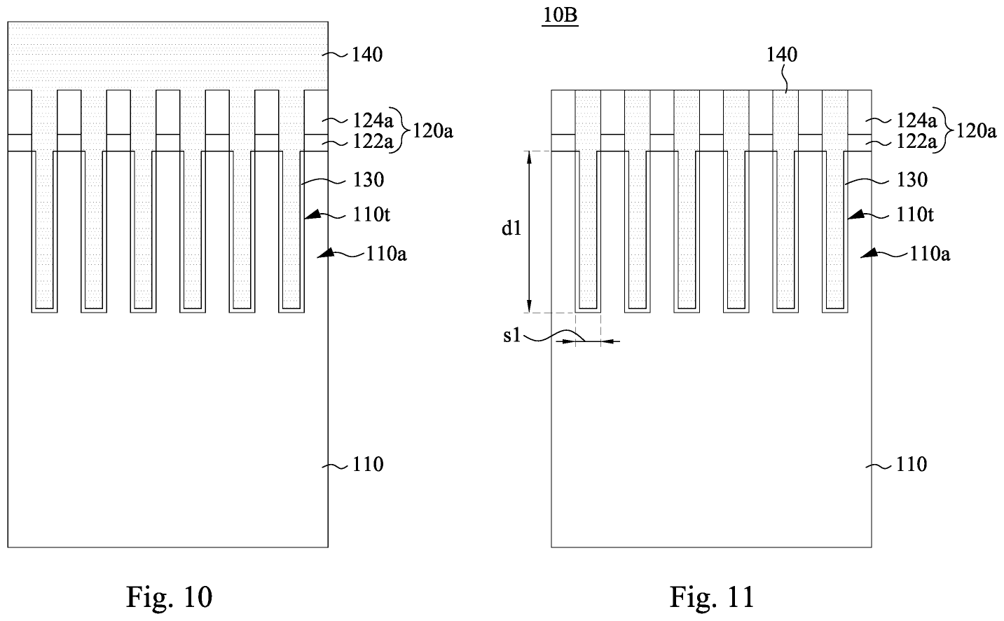

Next, as shown in FIGS. 10 and 11, a planarization process is performed to remove the isolation material 140 over the hard mask 120a. In some embodiments, the planarization process includes CMP.

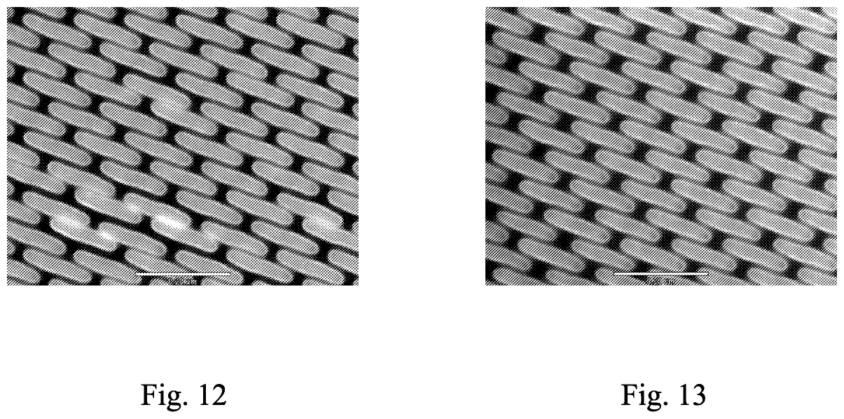

FIG. 12 is a SEM image of a semiconductor structure formed without a nitridation treatment. FIG. 13 is a SEM image of a semiconductor structure formed with a nitridation treatment in accordance with some embodiments of the present invention. FIG. 12 shows a plurality of island-shaped active regions, in which some active regions are toppled and in contact with adjacent active regions, which will induce twin bit fail issue and BL-BL leakage issue. However, as shown in FIG. 13, the island-shaped active regions are not toppled and are separated from each other, which can prove that the nitridation treatment is effective to prevent toppling of the active regions.

The present disclosure also provides a semiconductor structure manufacturing by the method mentioned above. Embodiments of the semiconductor structure will be described in detail below.

As shown in FIG. 7, a semiconductor structure 10A includes a substrate 110 and an isolation material 140. The substrate 110 has a plurality of active regions 110a separated from each other, in which a side surface of each of the active regions 110a of the substrate 110 includes nitrogen atoms. The isolation material 140 is filled between the active regions 110a.

In some embodiments, a spacing s1 between two adjacent of the active regions 110a is in a range of from 8 nm to 30 nm. In some embodiments, a ratio of a depth dl of one of the active regions 110a to the spacing s1 between two adjacent of the active regions 110a is in a range of from 8 to 18.

In some embodiments, the substrate 110 includes silicon, and the side surface of each of the active regions 110a of the substrate 110 includes nitrogen-doped silicon, silicon nitride or a combination thereof.

As shown in FIG. 11, a semiconductor structure 10B includes a substrate 110, an oxide-containing layer 130 and an isolation material 140. The substrate 110 has a plurality of active regions 110a separated from each other. The oxide-containing layer 130 is over a side surface of each of the active regions 110a, in which a side surface of the oxide-containing layer 130 includes nitrogen atoms. The isolation material 140 is filled between the active regions 110a.

In some embodiments, a spacing s1 between two adjacent of the active regions 110a is in a range of from 8 nm to 30 nm. In some embodiments, a ratio of a depth dl of one of the active regions 110a to the spacing s1 between two adjacent of the active regions 110a is in a range of from 8 to 18.

In some embodiments, the side surface of the oxide-containing layer 130 includes nitrogen-doped oxide, oxynitride or a combination thereof.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A method of manufacturing a semiconductor structure, comprising:
etching a substrate according to a hard mask to form a plurality of trenches in the substrate;
performing a nitridation treatment on the trenches of the substrate;
filling the trenches of the substrate with a flowable isolation material; and
solidifying the flowable isolation material to form an isolation material.

2. The method of claim 1, wherein the nitridation treatment comprises decoupled plasma nitridation (DPN), rapid thermal nitridation (RTN) or a combination thereof.

3. The method of claim 1, wherein there are nitrogen atoms on a side surface of each of the trenches after performing the nitridation treatment on the trenches of the substrate.

4. The method of claim 1, further comprising:
performing an oxidation treatment on the trenches of the substrate before performing the nitridation treatment on the trenches of the substrate.

5. The method of claim 4, wherein performing the oxidation treatment on the trenches of the substrate comprises forming an oxide-containing layer on a side surface of each of the trenches, and there are nitrogen atoms on a side surface of the oxide-containing layer after performing the nitridation treatment on the trenches of the substrate.

6. The method of claim 1, wherein filling the trenches of the substrate with the flowable isolation material is conducted by using a flowable chemical vapor deposition (CVD) process.

7. The method of claim 1, wherein solidifying the flowable isolation material comprises using a UV curing process, an annealing process or a combination thereof.

8. The method of claim 1, further comprising:
forming a hard mask layer over the substrate before etching the substrate; and
removing a plurality of portions of the hard mask layer to form the hard mask.

9. The method of claim 1, wherein a width of the trench is in a range of from 8 nm to 30 nm.

10. The method of claim 1, wherein a ratio of a depth of the trench to a width of the trench is in a range of from 8 to 18.
